(19) United States
(12) Patent Application Publication
(10) Pub. No.: US 2026/0239817 A1
(43) Pub. Date: Aug. 13, 2026

(54) ELECTROLUMINESCENT DEVICE, METHOD FOR MANUFACTURING SAME, AND DISPLAY DEVICE

(71) Applicant: Sharp Display Technology Corporation, Kameyama City, Mie (JP)

(72) Inventors: Masanobu MIZUSAKI, Kameyama City, Mie (JP); Katsuhiko KISHIMOTO, Kameyama City, Mie (JP)

(21) Appl. No.: 19/160,657

(22) PCT Filed: Mar. 6, 2023
(86) PCT No.: PCT/JP2023/008274

§ 371 Date: Aug. 28, 2025

(51) Int. Cl. H10K 50/13; H10K 50/12; H10K 50/19; H10K 71/16; H10K 101/00; H10K 102/00

(52) U.S. Cl. CPC H10K 50/13; H10K 50/12; H10K 50/19; H10K 71/166; H10K 2101/27; H10K 2102/3026

(57) ABSTRACT

An electroluminescent device includes a positive electrode layer, a negative electrode layer, an electroluminescent layer, and a charge generation layer. The electroluminescent layers include a plurality of electroluminescent layers and an electroluminescent layer. In the two electroluminescent layers adjacent in the stacking direction across the charge generation layer, the host compound in the electroluminescent layer closer to the positive electrode layer and the host compound in the electroluminescent layer closer to the negative electrode layer are formed of a same material, the guest compound in the electroluminescent layer closer to the positive electrode layer and the guest compound in the electroluminescent layer closer to the negative electrode layer are formed of a same material, and a concentration of the guest compound in the electroluminescent layer closer to the negative electrode layer is higher than the guest compound in the electroluminescent layer closer to the positive electrode layer.

### TECHNICAL FIELD

The present disclosure relates to an electroluminescent device, a method for manufacturing the electroluminescent device, and a display device.

### BACKGROUND ART

Mass production of displays equipped with organic-EL elements (also referred to as “organic light emitting diodes” or “OLEDs”) has started in earnest with highend thin displays for smartphones or TVs. Organic-EL element displays have become so widespread to be now the mainstream of thin displays replacing liquid crystal displays.

A thin film multilayer organic-EL element known in the art includes an electron transport electroluminescent layer formed of an aluminum quinolinol complex (Alq₃). However, in order to further improve light emission efficiency of the organic-EL element, developments are in progress in the order of (1) to (3) below.
(1) A host/guest material, which is obtained by adding a guest compound serving as a dopant to a host compound, is used as a material for an electroluminescent layer, a carrier (electrons and holes) transport layer, or a carrier (electrons and holes) injection layer of an organic-EL element.
(2) A fluorescent light emitting material or a combination of a fluorescent light emitting material and a phosphorescent light emitting material is used as a guest compound (a dopant) for the electroluminescent layer.
(3) An improved guest compound such as a thermally activated delayed fluorescent (TADF) material or a hyper fluorescent material is used as a dopant for the electroluminescent layer.

Furthermore, in view of increasing current efficiency and element lifetime of the organic-EL element, developments (4) and (5) below have been further studied.
(4) The carrier transport layer or the carrier injection layer is improved in order to improve the carrier balance.
(5) A tandem structure is employed as a structure of the light emitting element (see, for example, Patent Documents 1 to 3).

### CITATION LIST

### Patent Literature

[Patent Document 1] Japanese Unexamined Patent Application Publication No. 2007-329054
[Patent Document 2] International Publication No. WO/2010/113493
[Patent Document 3] Japanese Unexamined Patent Application Publication No. 2020-004970

### SUMMARY

### Technical Problem

However, when the light emitting layers are separately colored in RGB so that an image can be displayed in full color, and, simultaneously, the tandem structure is employed, the advantages of the employed tandem structure might not be sufficiently presented.

One aspect of the present disclosure sets out to provide a technique capable of sufficiently presenting advantages of employing a tandem structure for a full color electroluminescent device.

### Solution to Problem

An electroluminescent device according to an aspect of the present disclosure includes: a positive electrode layer; a negative electrode layer facing the positive electrode layer in a stacking direction; an electroluminescent layer including a plurality of electroluminescent layers disposed between the positive electrode layer and the negative electrode layer in the stacking direction, and in a direction intersecting with the stacking direction, the electroluminescent layers each containing a host compound and a guest compound; and a charge generation layer disposed between two of the electroluminescent layers adjacent to each other in the stacking direction. The electroluminescent layers include: a plurality of electroluminescent layers disposed in the stacking direction and emitting light in a same color; and an electroluminescent layer in a first color to an electroluminescent layer in an n-th color each disposed in a direction intersecting with the stacking direction and emitting light in a different color (where n is an integer of n≥2). In the two electroluminescent layers adjacent in the stacking direction across the charge generation layer, the host compound in the electroluminescent layer closer to the positive electrode layer and the host compound in the electroluminescent layer closer to the negative electrode layer are formed of a same material, the guest compound in the electroluminescent layer closer to the positive electrode layer and the guest compound in the electroluminescent layer closer to the negative electrode layer are formed of a same material, and a concentration of the guest compound in the electroluminescent layer closer to the negative electrode layer is higher than the guest compound in the electroluminescent layer closer to the positive electrode layer.

Furthermore, a display device according to an aspect of the present disclosure includes the electroluminescent device described above.

Moreover, a method for manufacturing an electroluminescent device according to an aspect of the present disclosure is directed to a method for manufacturing the electroluminescent device described above. The method includes a step of alternately stacking the electroluminescent layer and the charge generation layer with respect to the positive electrode layer or the negative electrode layer. The electroluminescent layer is formed by evaporation.

### Advantageous Effect of Disclosure

One aspect of the present disclosure can sufficiently present advantages of employing a tandem structure for a full color electroluminescent device.

### BRIEF DESCRIPTION OF DRAWINGS

FIG. 1 is a plan view schematically illustrating a configuration of a display device according to a first embodiment of the present disclosure.

FIG. 2 is a view schematically illustrating a layer configuration of the display device in FIG. 1.

FIG. 3 is a diagram schematically illustrating a layer configuration of an electroluminescent element in the layer configuration illustrated in FIG. 2.

FIG. 4 is a flowchart showing an exemplary method for manufacturing the electroluminescent element illustrated in FIG. 3.

FIG. 5 is a view showing a mechanism for emitting light from an electroluminescent element of the electroluminescent device in FIG. 2.

FIG. 6 is a view showing a mechanism for emitting light from an electroluminescent element of an electroluminescent device according to a second embodiment of the present disclosure.

### DESCRIPTION OF EMBODIMENTS

### Electroluminescent Element

An electroluminescent element according to an embodiment of the present disclosure has: a positive electrode layer; a negative electrode layer; an electroluminescent layer containing a host compound and a guest compound; and a charge generation layer. The electroluminescent element of the present disclosure has a plurality of electroluminescent layers overlapping with one another in a stacking direction. Furthermore, described below will be configurations of two electroluminescent layers adjacent in the stacking direction across the charge generation layer. A host compound in the electroluminescent layer closer to the positive electrode layer and a host compound in the electroluminescent layer closer to the negative electrode layer are formed of the same material. A guest compound in the electroluminescent layer closer to the positive electrode layer and a guest compound in the electroluminescent layer closer to the negative electrode layer are formed of the same material. A concentration of the guest compound in the electroluminescent layer closer to the negative electrode layer is higher than a concentration of the guest compound in the electroluminescent layer closer to the positive electrode layer. The electroluminescent element of the present disclosure may employ a known element structure for the light emitting element as long as the layers of the electroluminescent element satisfy these conditions. Described below will be a layer structure of the electroluminescent element of the present disclosure, mainly citing an OLED as an example. Note that, in the present disclosure, the term “electroluminescent element” refers to a group of electroluminescent layers and various carrier functional layers arranged in the stacking direction. Furthermore, in the present disclosure, the term “electroluminescent device” refers to a group of a plurality of electroluminescent elements provided in a direction intersecting in the stacking direction.

### Positive Electrode Layer

The positive electrode layer is one of a pair of electrode layers including a positive electrode and a negative electrode. In the present disclosure, the positive electrode layer is an electrode layer for supplying holes to each of the layers included in the electroluminescent element. The positive electrode layer is electrically conductive. Furthermore, the positive electrode layer has optical properties of, for example, reflecting visible light in part and transmitting the rest. Typically, the positive electrode layer contains both an electrode material reflecting visible light and an electrode material transmitting visible light.

As to the materials of the positive electrode layer, a material having a relatively large work function (e.g., a material having a work function of 4.5 eV or more) is preferably used in view of enhancing hole injection capability. Examples of the electrode material having a large work function include: Pt (5.65 eV), Ir (5.25 eV), Ni (5.2 eV), and Au and Pd (5.15 eV); and indium tin oxide (ITO).

Examples of the electrode material reflecting visible light include: metal materials such as Al, Mg, Li, Ag, Pd, and Cu; and an alloy of these metal materials (e.g., an APC (Ag—Pd—Cu) alloy).

Examples of the electrode material transmitting visible light include: a transparent metal oxide (e.g., indium tin oxide (In—Sn—O); a thin film formed of such a material as indium zinc oxide (In—Zn—O) or indium gallium zinc oxide (In—Ga—Zn—O); a thin film formed of such a metal material as Al, Mg, or Ag; and nanowires (NWs) formed of the metal materials.

Among transparent metal oxides, ITO has a relatively high work function of 4.6 to 5.0 eV. Hence, ITO is suitably used as a material for the positive electrode layer. Furthermore, the positive electrode layer can be a multilayer stack (e.g., ITO/Ag) containing a metal material and ITO formed on a surface of the metal material, in order to improve electrical conductivity as an electrode layer or to have an additional function of reflecting visible light.

### Negative Electrode Layer

The negative electrode layer is another one of the pair of electrode layers including the positive electrode and the negative electrode. In the present disclosure, the negative electrode layer is an electrode layer for supplying electrons to each of the layers included in the electroluminescent element. The negative electrode layer is disposed to face the positive electrode layer in the stacking direction. The negative electrode layer is, for example, electrically conductive and transparent to visible light.

As to the materials for the negative electrode layer, a material having a relatively small work function is preferably used in view of, for example, enhancing electron injection capability. Examples of an electrode material contained in the negative electrode layer include: a metal material such as alkali metal, alkali earth metal, or Al; an alloy containing these metals; and nanowires (e.g., Ag nanowires). Examples of the alloy include: an alloy of Mg and Ag; and Al doped with a small amount of Li.

### Electroluminescent Layer

The electroluminescent layer is a layer that emits light in a predetermined color when an electric field is applied thereto. The electroluminescent layer is usually formed of a light emitting material. Alternatively, the electroluminescent layer may have a multilayer structure with a plurality of functional layers: including two or more overlapping functional layers, such as a layer that emits light immediately and a layer that emits light slowly, in accordance with the two or more respective functions for electroluminescence of a known electroluminescent layer; and presenting electroluminescent functions as a whole. In the present disclosure, a plurality of the electroluminescent layers is disposed between the positive electrode layer and the negative electrode layer in the stacking direction, and in a direction intersecting with the stacking direction.

The electroluminescent layer includes a plurality of electroluminescent layers disposed in stacking direction and emitting light in the same color. The electroluminescent layers overlapping in the stacking direction and emitting light in the same color may be provided in any given number. In view of increasing light emission efficiency and element lifetime, preferably, two or more electroluminescent layers are provided, and, more preferably, three or more electroluminescent layers are be provided. Whereas, in view of reducing a rise in drive voltage, achieving a breakdown voltage of a drive driver in accordance with the drive voltage, and maintaining flexibility of the electroluminescent element (keeping the electroluminescent element from increasing in total thickness), preferably, five or fewer electroluminescent layers overlapping in the stacking direction and emitting light in the same color are provided, and, more preferably, four or fewer such electroluminescent layers are provided. Three or more electroluminescent layers are preferably five or fewer electroluminescent layers.

Here, the same color refers to colors of light rays with which, in a case where two or more peak emission wavelengths are found, all peak emission wavelengths are within a range of ±5 nm from one another, and a maximum value in full width at half maximum among all the peak emission wavelengths is 1.25 times or less than a minimum value in full width at half maximum among the remaining peak emission wavelengths. Basically, when both the host material and the guest compound contained in the electroluminescent layers are the same material or similar materials having the same skeleton, the electroluminescent layers emit light in the same color. Note that, in a top-emission structure to be described later, the peak emission wavelengths of the colors may vary because the microcavity structures are different depending on the colors. Hence, as to the top-emission structure, the same color refers to colors of light rays having all the peak emission wavelengths within a range of ±10 nm and satisfying the above range of the full width at half maximum. In the two electroluminescent layers adjacent in the stacking direction across the charge generation layer, a difference of 10 nm or less may be observed between a peak wavelength of an emission spectrum of the electroluminescent layer closer to the positive electrode layer and a peak wavelength of an emission spectrum of the electroluminescent layer closer to the negative electrode layer. In a plurality of electroluminescent layers disposed in the stacking direction, a difference of 10 nm or less may be observed between a maximum value of a peak wavelength of an emission spectrum and a minimum value of a peak wavelength of an emission spectrum. In a plurality of electroluminescent layers disposed in the stacking direction, a maximum value of full width at half maximum of a peak wavelength of an emission spectrum may be 1.25 times or less than a minimum value of full width at half maximum of a peak wavelength of an emission spectrum.

Furthermore, the electroluminescent layers include an electroluminescent layer in a first color to an electroluminescent layer in an n-th color each disposed in a direction intersecting with the stacking direction and emitting light in a different color (where n is an integer of n≥2). Here, the different colors include colors of light not included in the range of the same color described above. As a typically known example, light emitting layers having three colors of a red light emitting layer, a green light emitting layer, and a blue light emitting layer are known as electroluminescent layers in a plurality of colors for full color display. As can be seen, arranging the electroluminescent layers having a plurality of colors in the direction intersecting with the stacking direction is sometimes referred to as “separately colored”. Note that the number of electroluminescent layers in each color in the stacking direction is preferably the same for all the colors of emitted light. Hereinafter, the light emitting layers in the three colors described above will be mainly exemplified as the electroluminescent layers of the present disclosure; however, the present disclosure shall not be limited to such an example. Note that the electroluminescent layers in different colors from one another in the intersecting direction may be at the same position (at the same height), or at different positions (at different heights); that is, may be displaced, in the stacking direction.

That is, in the present disclosure, when the electroluminescent device includes electroluminescent layers in three colors of red, green and blue, the electroluminescent elements in the three colors are independently arranged in a direction intersecting with the stacking direction; that is, for example, in a direction perpendicular to the stacking direction. Furthermore, in the stacking direction, the red electroluminescent layer includes red electroluminescent layers stacked on top of another, the green electroluminescent layer includes green electroluminescent layers stacked on top of another, and the blue electroluminescent layer includes blue electroluminescent layers stacked on top of another. Note that, an electroluminescent layer in a different color may further be stacked in the stacking direction. However, in view of color purity, a plurality of electroluminescent layers disposed in the stacking direction emits light preferably only in the same color. The feature that the electroluminescent layers only in the same color are stacked in the stacking direction is advantageous in view of more readily determining a concentration of the guest compound (a dopant concentration) contained in each of the electroluminescent layers.

In an electroluminescent element having three or more electroluminescent layers arranged in the stacking direction, when a charge generation layer is provided between the electroluminescent layers, if the carriers (the electrons and/or the holes) are supplied optimally to an electroluminescent layer in one direction in the stacking direction with respect to a charge generation layer, the electrons and/or the holes might be supplied in control; that is, insufficiently, to an electroluminescent layer in another direction in the stacking direction. As a result, the carriers might be imbalanced among the plurality of electroluminescent layers. In the present disclosure, a concentration of the guest compound in the electroluminescent layer provided closer to the positive electrode layer and receiving an insufficient amount of controlled carriers (the electrons) is set lower than a concentration of the guest compound in the electroluminescent layer closer to the negative electrode layer. Conversely, the concentration of the guest compound in the electroluminescent layer closer to the negative electrode layer is set higher than the concentration of the guest compound in the electroluminescent layer closer to the positive electrode layer. Such features optimize the balance of the carriers among all the electroluminescent layers in the stacking direction.

Specifically, as to the electroluminescent device of the present disclosure, in the two electroluminescent layers adjacent in the stacking direction across the charge generation layer, a host compound of an electroluminescent layer closer to the positive electrode layer and a host compound of an electroluminescent device closer to the negative electrode layer are a same material, a guest compound of the electroluminescent layer closer to the positive electrode layer and a guest compound of the electroluminescent device closer to the negative electrode layer are a same material, and a concentration of the guest compound in the electroluminescent layer closer to the negative electrode layer is higher than a concentration of the guest compound in the electroluminescent layer closer to the positive electrode layer. If three or more electroluminescent layers are arranged in the stacking direction, among the three or more electroluminescent layers, an electroluminescent layer farther away from the positive electrode layer preferably exhibits a higher concentration of the guest compound. Note that the term “adjacent” as to the electroluminescent layers means that, when the electroluminescent layers included in the electroluminescent element are arranged, the electroluminescent layers are positioned adjacent to each other in the stacking direction. That is, the electroluminescent layers adjacent in the stacking direction may have another layer provided therebetween. The concentration of the guest compound is represented by a mass of the guest compound with respect to a sum of a mass of the host compound and the mass of the guest compound. Examples of a technique for measuring the concentration of the guest compound include: measuring an emission spectrum; measuring time-resolved emission properties; measuring an absorption spectrum; ¹H-NMR or ¹³C-NMR; mass spectrometry; and a combination of at least two of these techniques.

Thanks to such a feature, in the electroluminescent device of the present disclosure, the carriers are optimally balanced among the electroluminescent layers in the stacking direction. The concentration of the guest compound in each of the electroluminescent layers can be appropriately determined depending on various factors such as a combination of materials for the layers included in the electroluminescent element and a purpose of varying the concentration of the guest compound in each electroluminescent layer, as long as the determined concentration meets the technical concept of the present disclosure.

The electroluminescent layers of the present disclosure are host/guest electroluminescent layers containing a host compound and a guest compound. Each of the host/guest electroluminescent layers is formed of: a solid medium serving as a host compound; and a small amount (e.g., approximately 0.1 to several wt %) of fluorescent dopant serving as, for example, the guest compound. As can be seen, the electroluminescent layer doped with the guest compound completely loses fluorescence of the host compound, and, instead, emits strong light matching a fluorescent spectrum of the guest compound with which the electroluminescent layer is doped. This is because excitation energy of the host compound transfers to the guest compound. Thanks to the transfer of the excitation energy, in the host/guest electroluminescent layer, the guest compound with higher quantum efficiency emits light.

A concentration of the guest compound in the electroluminescent layer closer to the negative electrode layer is lower than, or equal to, twice a concentration of the guest compound in the electroluminescent layer closer to the positive electrode layer. In the two electroluminescent layers adjacent in the stacking direction across the charge generation layer, the guest compound of the electroluminescent layer closer to the positive electrode layer and the guest compound of the electroluminescent layer closer to the negative electrode layer may be either a fluorescent dopant or a phosphorescent dopant. The guest compound of the electroluminescent layer in a first color may be a fluorescent dopant, and the guest compound of the electroluminescent layer in a second color may be a phosphorescent dopant. An emission spectrum of the electroluminescent layer containing the guest compound may have a peak wavelength of 440 nm or more and 660 nm or less. In the two electroluminescent layers adjacent in the stacking direction across the charge generation layer, the guest compound of the electroluminescent layer closer to the positive electrode layer and the guest compound of the electroluminescent layer closer to the negative electrode layer may be a hole transport material. In the two electroluminescent layers adjacent in the stacking direction across the charge generation layer, the guest compound of the electroluminescent layer closer to the positive electrode layer and the guest compound of the electroluminescent layer closer to the negative electrode layer may be an electron transport material. Here, the hole transport material refers to a material having holes relatively stably and moving the holes with an electric field. Furthermore, the electron transport material refers to a material having electrons relatively stably and moving the electrons with an electric field. Note that a delayed fluorescent dopant, a thermally-activated fluorescent dopant, and a fluorescent dopant that emits light through a delayed fluorescent material (a hyper fluorescence) are included within a scope of the fluorescent dopant (i.e., modified fluorescent dopants).

The emission spectrum of the electroluminescent layer containing the guest compound has a peak wavelength of 440 nm or more and 660 nm or less. Such a feature makes it possible to display an image in full color, which presents a sufficiently wide range of color gamut to be expressed. Furthermore, the guest compound of the electroluminescent layer closer to the positive electrode layer and the guest compound of the electroluminescent layer closer to the negative electrode layer are formed of a hole transport material. Thanks to such a feature, the balance of the carriers is readily adjusted by varying concentrations of the guest compounds. Moreover, the guest compound of the electroluminescent layer closer to the positive electrode layer and the guest compound of the electroluminescent layer closer to the negative electrode layer are formed of an electron transport material. Thanks to such a feature, the balance of the carriers is readily adjusted by varying concentrations of the guest compounds.

In addition, the electroluminescent layers are doped with a fluorescent dopant serving as a guest compound. Such a feature drastically increases element lifetime of the electroluminescent element. This is because the dopant serving as the guest compound functions as a trap of the carriers (the electrons or the holes) in the solid medium of the host compound, serves as a recombination center of the carriers, and directly generates excitons in the solid medium. When the generated excitons relax to the ground state, the process is referred to as a deactivation process. The deactivation process includes: a non-radiation process (thermal deactivation) and a radiation process (light emission), and a phenomenon of emitting light through the radiation process is electroluminescence. The guest compound functions as a trap of the carriers. Such a feature contributes not only to an increase in the quantum efficiency of the electroluminescent layers but also to an increase in the element lifetime because of an increase in probability for the recombination of the carriers. As a result, the electroluminescent layers increase in light emission efficiency and the electroluminescent element increases in lifetime.

As can be seen, the host/guest electroluminescent layers can effectively use the carriers. Hence, the electroluminescent device of the present disclosure increases light emission efficiency of the electroluminescent layers and element lifetime of the electroluminescent element.

Note that the excitons to be generated when carries are recombined include singlet excitons and triplet excitons. When the fluorescent dopant is used as the guest compound, the singlet excitons contribute to emission of light. Here, if the phosphorescent dopant is used instead of the fluorescent dopant, the triplet excitons contribute to emission of light. The singlet excitons and the triplet excitons respectively account for 25% and 75% of the generated excitons, which is obtained according to the spin statistics theorem. Hence, if the fluorescent dopant is used as the guest compound, that is, in the process of emitting “fluorescent light” only from the singlet excitons, a probability of generating excitons contributing to the emission of light is 25% at most.

Whereas, if the phosphorescent dopant is used as the guest compound, the light can be released from the triplet excitons. Hence, the quantum efficiency of the phosphorescent dopant can be increased threefold higher than quantum efficiency of the fluorescent dopant. Furthermore, with use of the intersystem crossing; that is, inversion of spin from the singlet excitons to the triplet excitons, theoretically all the generated excitons can emit the “phosphorescent light” from triplet excitons. Hence, if the phosphorescent dopant is used as the guest compound, the quantum efficiency of the phosphorescent can be increased up to fourfold higher than the quantum efficiency of the fluorescent dopant.

Each of the electroluminescent layers may be formed of a known light emitting material. For example, examples of the light emitting material forming the blue electroluminescent layer include such fluorescent dopants as a pyrene-based compound and an anthracene-based compound. Furthermore, examples of the light emitting material forming the red electroluminescent layer and the green electroluminescent layer include such phosphorescent dopants as an iridium complex and a palladium-based complex.

Note that complexes containing such a platinum-based element as iridium or palladium used as the phosphorescent dopant are extremely expensive even in a small amount and might not be in constant supply because the production amount of platinum-based elements is small, and the production sites are unevenly distributed. Hence, it is extremely important to reduce the usage of phosphorescent dopants formed of the platinum-based complexes in view of reducing costs and economic security.

Thus, the host/guest electroluminescent layer can be formed of a host compound doped with a guest compound. The host/guest electroluminescent layer can be formed by simultaneous evaporation, using a plurality of evaporation sources.

The host/guest electroluminescent layer can be formed of publicly known various exemplary materials. Examples of the host compound include publicly known materials for the light emitting layers in the three colors. Examples of the guest compound include: the fluorescent dopant and the phosphorescent dopant described before; a TADF material; and a hyper fluorescent material. Other examples of fluorescent dopants include: perylene; DPT; Coumarin 6; PMDFB; quinacridone; rubrene; BTX; ABTX; DCM; and DCJT. Other examples of the phosphorescent dopant include: Ir(ppy)₃; Ir(thpy)₃; Ir(t5m-thpy)₃; Ir(t-5CF₃-py)₃; Ir(t-5t-py)₃; Ir(mt-5mt-py)₃; Ir(btpy)₃; Ir(tflpy)₃; Ir(piq)₃; Ir(tiq)₃; Ir(fliq)₃; FIrpic; FIr6; ppy; tpy; bzq; thp; op; bo; bt; bon; absn; btp; ppo; C6; pq; β-bsn; and ppz.

Note that, as to an electroluminescent element currently in the mainstream, an electroluminescent layer that emits light in blue is formed of a fluorescent dopant serving as the guest compound, and electroluminescent layers that emit light in red and green are formed of a phosphorescent dopant serving as the guest compound. As to the electroluminescent device including such electroluminescent elements, the quantum efficiency of the fluorescent dopant is lower than the quantum efficiency of the phosphorescent dopant both in theory and in practice. Hence, in the electroluminescent device described above, the blue electroluminescent layer is supplied with a current in larger amount than the red or green electroluminescent layer, so that the amount of light to be emitted from the layers are well balanced.

### Charge Generation Layer

The charge generation layer is disposed between the two electroluminescent layers adjacent in the stacking direction. The charge generation layer is a layer that generates, the electrons or the holes, or both the electrons and the holes. The electric charges (i.e., charges or carriers) generated in the charge generation layer are supplied to the electroluminescent layers each positioned toward one of the positive electrode layer and the negative electrode layer in the stacking direction. The charge generation layer may be formed of a known charge generation material having the function described above.

The charge generation layer can include: an electron generation layer that generates electrons; and a hole generation layer that generates holes. The electron generation layer is, for example, an n-type charge generation layer, and the hole generation layer is, for example, a charge generation layer. When the holes are supplied from the positive electrode layer, and the electrons are supplied from the negative electrode layer, the n-type charge generation layer generates the electrons, and the p-type charge generation layer generates the holes.

The p-type charge generation layer can be formed of a material containing: an organic hole transport material; and organic electron acceptance material (a hole generation material) added in a range of 1 to 10%. The organic hole transport material can be a publicly known triarylamine-based organic compound. Examples of the organic electron acceptance material include tetracyanoquinodimethane tetrafluoride (TCNQ-4F). The p-type charge generation layer is formed of the hole transport material and the electron acceptance material described above. All of the materials for the p-type charge generation layer are organic materials sufficiently capable of generating the holes.

The n-type charge generation layer can be formed of a material containing, for example, an organic electron transport material and either Yb (ytterbium) or Li (lithium) that is an inorganic metal material added in a range of 5 to 20%. Yb or Li serves as an electron generation material. The organic electron transport material is, for example, an oxadiazole-based compound. As to the n-type charge generation layer, development is proceeding so that both an electron transport layer and the electron generation material are formed of an organic material. For example, such materials as BUPH1, BPen, p-MeO-Phen, p-NMe2-Phen, and p-Pyrrd-Phen are under development as the organic electron generation material.

At present, there is no organic electron generation material sufficiently capable of supplying electrons and applicable to the n-type charge generation layer. Hence, there is no n-type charge generation layer formed entirely of an organic material and having sufficient properties. According to the present disclosure, the concentration of the guest compound in each of the electroluminescent layers is set as described above. Such a feature can optimize a balance (a carrier balance) between the electrons and/or the holes supplied from the charge generation layer and the holes and/or the electrons supplied from each of the electrode layers. Hence, the present disclosure provides a tandem electroluminescent device reducing generation of excess carriers and having a plurality of electroluminescent layers operating on low power.

### Other Configurations

The electroluminescent element of the present disclosure may further include other layers within the scope of the advantageous effects of the present disclosure. Examples of the other configurations include such carrier functional layers as a hole injection layer, an electron injection layer, a hole transport layer, an electron blocking layer, a hole blocking layer, and an electron transport layer.

The hole injection layer is disposed adjacent to, for example, the positive electrode layer. The hole injection layer can be formed of a hole transport material and an electron acceptance material. These materials are the same organic materials described for the p-type charge generation layer. As to the electroluminescent element, specific materials for the hole injection layer may be the same as, or different from, the materials for the p-type charge generation layer.

The electron injection layer is disposed adjacent to, for example, the negative electrode layer. The electron injection layer can be formed of an electron transport material. Examples of the electron transport material forming the electron injection layer include lithium fluoride (LiF); that is, an inorganic material. Furthermore, similar to the n-type charge generation layer, the electron injection layer may contain an electron transport material formed of an organic material such as an oxadiazole-based compound and doped with a metal material (e.g., Li or Yb).

LiF used for the electron injection layer is highly capable of injecting electrons. Whereas, an inorganic material including not only LiF but also Yb has a high melting point. Hence, the carrier functional layers containing such an inorganic material is deposited at a temperature higher than a deposition temperature of an electroluminescent layer and a carrier functional layer typically formed of an organic material. Thus, the carrier functional layers might thermally damage an organic material deposited in advance. Hence, as much as possible, the electroluminescent element is preferably formed only of an organic material.

That is why organic electron injection materials such as BUPH1, BPen, p-MeO-Phen, p-NMe2-Phen, and p-Pyrrd-Phen are under development because these organic electron injection materials exhibit sufficient properties in combination with a cathode layer formed of such a material as aluminum (Al) capable of forming an evaporation layer at a relatively low temperature. However, an electron injection layer formed of an organic material is inferior in injection of electrons to an electron injection layer formed of such an inorganic material as LiF described above. Hence, when the electron injection layer formed of an organic material is disposed adjacent to the negative electrode layer, there might be a reduction in the amount of electrons to be supplied to the electroluminescent layer formed toward the negative electrode layer. In such a case, a concentration of the guest compound (i.e., a doping concentration) in the electroluminescent layer closer to the negative electrode layer is decreased below a theoretical value in order to reduce an effect of the reduction in the amount of the supplied electrons. Such a feature can sufficiently provide advantages of employing the tandem structure. In this case, in order to reduce an imbalance of the carriers, effectively, a doping concentration observed in the electroluminescent layer closer to the positive electrode layer is reduced at a specific rate with respect to the doping concentration observed in the electroluminescent layer closer to the negative electrode layer and decreased below a theoretical doping concentration. The present disclosure may include such a configuration.

The hole transport layer can be formed of an organic hole transport material such as, for example, a triarylamine-based organic compound.

Similar to the hole transport layer, the electron blocking layer can also be formed of an organic hole transport material. The electron blocking layer may be formed of the same material as, or a different material from, the material of the hole transport layer.

The hole blocking layer can be formed of such an organic electron transport material as, for example, an oxadiazole-based compound. The material for the hole blocking layer may contain lithium quinoline (Liq) in addition to the electron transport material.

Similar to the hole blocking layer, the electron transport layer can also be formed of the organic electron transport material described before. The electron transport layer may be formed of the same material as, or a different material from, the material of the hole blocking layer.

The hole injection layer and the electron injection layer may be disposed in association with the electrode layers. Usually, the hole injection layer and the electron injection layer are disposed adjacent to the respective electrode layers in the stacking direction. A plurality of the hole transport layers, the electron blocking layers, the electroluminescent layers, the hole blocking layers, the electron transport layers, and the charge generation layers can be repeatedly overlapped with one another and disposed in the stacking direction of the electroluminescent element.

The electroluminescent device of the present disclosure is suitable for a top-emission electroluminescent device capable of full color display. The top-emission electroluminescent device utilizes the microcavity effect obtained by adjusting a distance between the electrode layers in accordance with a wavelength of light emitted from light emitting layers in the respective colors, thereby successfully enhancing light extraction efficiency. For this purpose, any one or more of the carrier functional layers may be formed thick. The electroluminescent device of the present disclosure has a so-called tandem structure including a plurality of electroluminescent layers and carrier functional layers each corresponding to one of the electroluminescent layers. Such a feature can reduce the thickness of the carrier functional layers for adjusting the distance between the electrode layers, and further reduce consumption of functionally unnecessary materials.

### Stack

A stack is a layer group including one electroluminescent layer disposed between a positive electrode layer and a charge generation layer, between charge generation layers, and between a charge generation layer and a negative electrode layer in the stacking direction. The stack can include a carrier functional layer in addition to the one electroluminescent layer. A plurality of the stacks may be disposed between the positive electrode layer and the negative electrode layer in the stacking direction. Note that, in the present disclosure, none of such layers as the positive electrode layer, the negative electrode layer, and the charge generation layer is included in the stack.

A thickness of the stack is determined so that the amount of light emitted from the electroluminescent layer is equal to, or close to, a theoretical value. In the present disclosure, preferably, the thickness of the stack is determined in accordance with a thickness of the electroluminescent layer in view of enhancing light emission efficiency of the light emitting element. Note that the thickness of the stack is obtained as a sum of the thicknesses of the electroluminescent layer and the carrier functional layers in the stack. However, among the electroluminescent layer and the carrier functional layers, a very thin layer (e.g., a layer having a thickness of 1 nm or less) may be ignored in calculating the thickness of the stack.

### Method for Manufacturing Electroluminescent Device

A method for manufacturing an electroluminescent device according to the present disclosure is a method for manufacturing the electroluminescent device described above. The method includes a step of alternately stacking electroluminescent layers and charge generation layers with respect to the positive electrode layer or the negative electrode layer. In addition, in view of precisely controlling the thickness and the concentration of the electroluminescent layer in the electroluminescent device of the present disclosure, the manufacturing method preferably involves forming at least the electroluminescent layer by evaporation. The electroluminescent layer formed by evaporation is usually preferable in view of achieving high luminance and low drive voltage, and is also preferable in view of providing a display device with high definition because such an electroluminescent layer can highly precisely form an electroluminescent element including fine pixels. Furthermore, simultaneous evaporation using a plurality of evaporation sources is more preferable because the simultaneous evaporation can form a host/guest electroluminescent layer.

The electroluminescent device of the present disclosure, repeatedly having a specific layer structure, can be manufactured by repeatedly forming a specific layer twice or more. In the present disclosure, in forming a plurality of electroluminescent layers that emits light in the same color in the stacking direction, preferably, an evaporation time period of the guest compound is different for each of the electroluminescent layers. In the present disclosure, in forming a plurality of electroluminescent layers that emits light in the same color in the stacking direction, more preferably, only an evaporation time period of the guest compound is different for each of the electroluminescent layers. Such a manufacturing method makes it possible to keep conditions constant (e.g., a temperature of a melting pot (an evaporation temperature), an evaporation rate to be controlled by such a factor as the evaporation temperature, a ratio of the host compound to the guest compound, and an evaporation mask to define a shape of a pixel) except for a time period for evaporation in forming the electroluminescent layers. Such a feature reduces variations in properties of the electroluminescent layers in the stacking direction because of variations in the conditions, thereby making it possible to achieve advantageous effects due to the difference between the guest compound concentrations (the doping concentrations) of the electroluminescent layers in the stacking direction. In the present disclosure, in forming the plurality of electroluminescent layers that emits light in the same color in the stacking direction, an evaporation temperature of the guest compound may be different for each of the electroluminescent layers.

### Display Device

The display device according to the present disclosure includes the electroluminescent device described above. The display device of the present disclosure can be the same as a known display device having a known light emitting device except for the electroluminescent device described above. Examples of the display device include such devices as a television device and a smartphone.

### Specific Aspects

An electroluminescent device, a method for manufacturing the electroluminescent device, and a display device of the present disclosure will be described more specifically below with reference to the drawings, taking, as an example, an electroluminescent device including organic light emitting diodes (OLEDs). In the Description, features in different colors among the like basic features are denoted with signs representing colors in addition to the signs of the basic features. For example, a feature in relation to red is accompanied with an additional sign “R”, a feature in relation to green is accompanied with an additional sign “G”, and a feature in relation to blue is accompanied with an additional sign “B”.

### First Embodiment

### Configuration

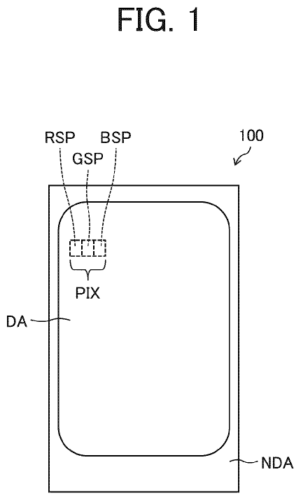

FIG. 1 is a plan view schematically illustrating a configuration of a display device 100 according to a first embodiment of the present disclosure. FIG. 1 shows a smartphone as an example of a display device. As illustrated in FIG. 1, the display device 100 includes a picture-frame region NDA and a display region DA. The display region DA of the display device 100 includes a plurality of pixels PIX. Each of the pixels PIX includes a red subpixel RSP, a green subpixel GSP, and a blue subpixel BSP.

Note that a configuration of each of the pixels in the display device according to the present disclosure shall not be limited to the above configuration. As to the display device of the present disclosure, for example, one pixel PIX may further include a subpixel in another color, in addition to the red subpixel RSP, the green subpixel GSP, and the blue subpixel BSP.

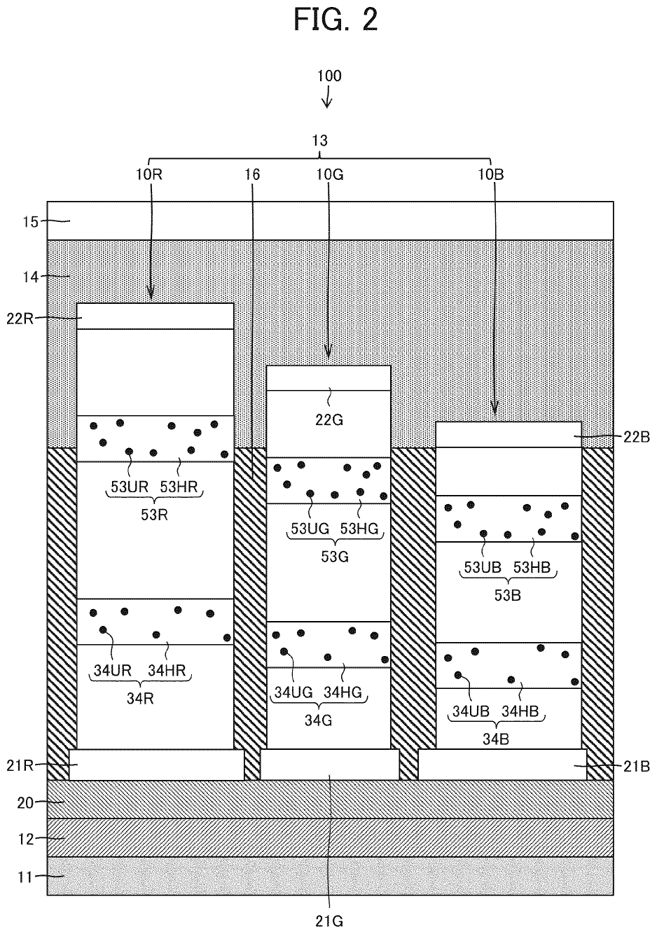

FIG. 2 is a view schematically illustrating a layer configuration of the display device 100 in FIG. 1. As illustrated in FIG. 2, the display device 100 includes: a substrate 11; a buffer layer 12; a thin film transistor (TFT) layer 20 including a pixel circuit; an electroluminescent device 13 and an edge cover film 16; a sealing layer 14; and an external functional layer 15, all of which are stacked on top of another in the stated order.

The substrate 11 is either a glass substrate or a flexible substrate mainly made of a resin such as polyimide. For example, the substrate 11 can be formed of: two polyimide films; and an inorganic film sandwiched between the two polyimide films.

The buffer layer 12 can be an inorganic insulating layer that prevents entry of foreign substances such as water and oxygen. The TFT layer 20 includes a pixel circuit that controls a red electroluminescent element 10R, a green electroluminescent element 10G, and a blue electroluminescent element 10B.

The electroluminescent device 13 includes: the red electroluminescent element 10R; the green electroluminescent element 10G; and the blue electroluminescent element 10B. The red electroluminescent element 10R includes: a positive electrode layer 21R; a negative electrode layer 22R; and a first electroluminescent layer 34R and a second electroluminescent layer 53R between the positive electrode layer 21R and the negative electrode layer 22R. Likewise, the green electroluminescent element 10G includes: a positive electrode layer 21G; a fist electroluminescent layer 34G; a second electroluminescent layer 53G; and a negative electrode layer 22G. The blue electroluminescent element 10B includes: a positive electrode layer 21B; a fist electroluminescent layer 34B; a second electroluminescent layer 53B; and a negative electrode layer 22B.

Here, in FIG. 2, the red electroluminescent element 10R, the green electroluminescent element 10G, and the bleu electroluminescent element 10B are respectively provided with the negative electrode layer 22R, the negative electrode layer 22G, and the negative electrode layer 22B. A configuration of the electroluminescent device 13 of the present disclosure shall not be limited to this configuration. For example, the negative electrode layer 22R, the negative electrode layer 22G, and the negative electrode layer 22B may be a common electrode layer provided across the red electroluminescent element 10R, the green electroluminescent element 10G, and the blue electroluminescent element 10B.

The sealing layer 14 covering the electroluminescent device 13 is a layer for preventing foreign substances such as water and oxygen from penetrating into the electroluminescent device 13. The sealing layer 14 can include, for example, two inorganic sealing films and an organic film formed between the two inorganic sealing films. The external functional layer 15 is a layer to additionally provide the display device 100 with such various functions as an optical control function, a touch sensor function, and a surface protection function.

The edge cover film 16, which is insulative, covers an edge of each of the positive electrode layers 21R, 21G, and 21B. In forming the edge cover film 16, for example, an organic material such as polyimide or acrylic resin is applied. After that, the applied organic material is patterned by photolithography to form the edge cover film 23. Note that the each of the red electroluminescent element 10R, the green electroluminescent element 10G, and the blue electroluminescent element 10B is, for example, an organic light emitting diode (an OLED).

The first electroluminescent layer 34R contains: a host compound 34HR; and a guest compound 34UR. The second electroluminescent layer 53R contains: a host compound 53HR; and a guest compound 53UR. The first electroluminescent layer 34G contains: a host compound 34HG; and a guest compound 34UG. The second electroluminescent layer 53G contains: a host compound 53HG; and a guest compound 53UG. The first electroluminescent layer 34B contains: a host compound 34HB; and a guest compound 34UB. The second electroluminescent layer 53B contains: a host compound 53HB; and a guest compound 53UB.

The host compound 34HR and the host compound 53HR are formed of the same material. The host compound 34HG and the host compound 53HG are formed of the same material. The host compound 34HB and the host compound 53HB are formed of the same material.

The guest compound 34UR and the guest compound 53UR are formed of the same material. The guest compound 34UG and the guest compound 53UG are formed of the same material. The guest compound 34UB and the guest compound 53UB are formed of the same material.

A concentration of the guest compound 53UR in the second electroluminescent layer 53R is higher than a concentration of the guest compound 34UR in the first electroluminescent layer 34R. A concentration of the guest compound 53UG in the second electroluminescent layer 53G is higher than a concentration of the guest compound 34UG in the first electroluminescent layer 34G. A concentration of the guest compound 53UB in the second electroluminescent layer 53B is higher than a concentration of the guest compound 34UB in the first electroluminescent layer 34B.

A concentration of the guest compound 53UR in the second electroluminescent layer 53R is lower than, or equal to, twice a concentration of the guest compound 34UR in the first electroluminescent layer 34R. A concentration of the guest compound 53UG in the second electroluminescent layer 53G is lower than, or equal to, twice a concentration of the guest compound 34UG in the first electroluminescent layer 34RG. A concentration of the guest compound 53UB in the second electroluminescent layer 53B is lower than, or equal to, twice a concentration of the guest compound 34UB in the first electroluminescent layer 34UB. If the concentration is higher than twice, the second electroluminescent layer provided closer to the negative electrode layer and having a high concentration of the guest compound causes quenching by itself, such that generated excitons are consumed wastefully. Furthermore, the first electroluminescent layer provided closer to the positive electrode layer and having a low concentration of the guest compound might not generate sufficient excitons.

A difference of 10 nm or less may be observed between a peak wavelength of an emission spectrum of the first electroluminescent layer 34R and a peak wavelength of an emission spectrum of the second electroluminescent layer 53R. A difference of 10 nm or less may be observed between a peak wavelength of an emission spectrum of the first electroluminescent layer 34G and a peak wavelength of an emission spectrum of the second electroluminescent layer 53G. A difference of 10 nm or less may be observed between a peak wavelength of an emission spectrum of the first electroluminescent layer 34B and a peak wavelength of an emission spectrum of the second electroluminescent layer 53B.

Full width at half maximum of the peak wavelength of the emission spectrum of the first electroluminescent layer 34R may be 0.8 times or more and 1.25 times or less than full width at half maximum of the peak wavelength of the emission spectrum of the second electroluminescent layer 53R. Full width at half maximum of the peak wavelength of the emission spectrum of the first electroluminescent layer 34G may be 0.8 times or more and 1.25 times or less than full width at half maximum of the peak wavelength of the emission spectrum of the second electroluminescent layer 53G. Full width at half maximum of the peak wavelength of the emission spectrum of the first electroluminescent layer 34B may be 0.8 times or more and 1.25 times or less than full width at half maximum of the peak wavelength of the emission spectrum of the second electroluminescent layer 53B.

The guest compounds 34UR and 53UR may be either a fluorescent dopant or a phosphorescent dopant. The guest compounds 34UG and 53UG may be either a fluorescent dopant or a phosphorescent dopant. The guest compounds 34UB and 53UB may be either a fluorescent dopant or a phosphorescent dopant.

Any one of pairs of the guest compounds 34UR and 53UR, a pair of the guest compounds 34UG and 53UG, or a pair of the guest compounds 34UB and 53UB (a guest compound of an electroluminescent layer in a first color) may be a fluorescent dopant, and another pair (a guest compound of an electroluminescent layer in a second color) may be a phosphorescent dopant.

The peak wavelength of the emission spectrum of each of the first electroluminescent layer 34R and the second electroluminescent layer 53R may be 440 nm or more and 660 nm or less. The peak wavelength of the emission spectrum of each of the first electroluminescent layer 34G and the second electroluminescent layer 53G may be 440 nm or more and 660 nm or less. The peak wavelength of the emission spectrum of each of the first electroluminescent layer 34B and the second electroluminescent layer 53B may be 440 nm or more and 660 nm or less.

The guest compounds 34UR and 53UR may also be hole transport materials. The guest compounds 34UG and 53UG may also be hole transport materials. The guest compounds 34UB and 53UB may also be hole transport materials.

The guest compounds 34UR and 53UR may also be electron transport materials. The guest compounds 34UG and 53UG may also be electron transport materials. The guest compounds 34UB and 53UB may also be electron transport materials.

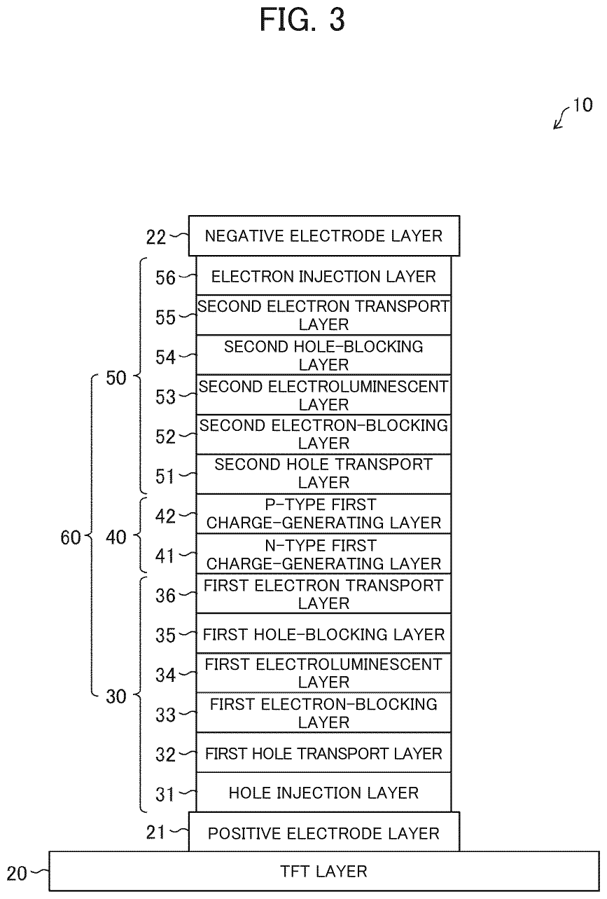

With reference to FIG. 3, an element configuration of the electroluminescent element 10 in FIG. 2 will be described. FIG. 3 is a diagram schematically illustrating a layer configuration of an electroluminescent element in the layer configuration illustrated in FIG. 2.

As illustrated in FIG. 3, the substrate 11, the buffer layer 12, and the TFT layer 20 are stacked on top of another in the stated order. The electroluminescent element 10 includes: the positive electrode layer 21; a layer group 30; a first charge generation layer 40; a layer group 50; and the negative electrode layer 22, all of which are stacked on top of another in the stated order above the TFT layer 20. The electroluminescent element 10 according to the present disclosure is a top-emission electroluminescent element (having a structure releasing light from above; that is, from toward the negative electrode layer 22). As to the electroluminescent element 10, for example, the positive electrode layer 21 functions as an anode, and the negative electrode layer 22 functions as a cathode.

The layer group 30 includes: a hole injection layer 31; a first hole transport layer 32; a first electron blocking layer 33; a first electroluminescent layer 34; a first hole blocking layer 35; and a first electron transport layer 36. The layer group 50 includes: a second hole transport layer 51; a second electron blocking layer 52; a second electroluminescent layer 53; a second hole blocking layer 54; a second electron transport layer 55; and an electron injection layer 56. Provided between the layer group 30 and the layer group 50 is the first charge generation layer 40 including: an n-type first charge generation layer (electron generation layer) 41; and a p-type first charge generation layer (hole generation layer) 42. In the electroluminescent element 10 of FIG. 3, the layer group 30 is also referred to as a “first stack”, and the layer group 50 is also referred to as a “second stack”. The layer group 30, the first charge generation layer 40, and the layer group 50 constitute an organic multilayer stack 60.

The hole injection layer 31, the first hole transport layer 32, the first electron blocking layer 33, the first hole blocking layer 35, the first electron transport layer 36, the n-type first charge generation layer 41, the p-type first charge generation layer 42, the second hole transport layer 51, the second electron blocking layer 52, the second hole blocking layer 54, the second electron transport layer 55, and the electron injection layer 56 are carrier functional layers that contribute to at least one of injection, movement, or generation of carriers (electrons or holes).

The electroluminescent element 10 is what is referred to as a tandem electroluminescent element in which two electroluminescent layers of the first electroluminescent layer 34 and the second electroluminescent layer 53 are arranged between the positive electrode layer 21 and the negative electrode layer 22 in the stacking direction. The first electroluminescent layer 34 and the second electroluminescent layer 53, which overlap in the stacking direction, are electroluminescent layers that emit light in the same color.

A thickness and a guest compound concentration (a dopant concentration) of the first electroluminescent layer 34 vary depending on a color of the light to be emitted. For example, the first electroluminescent layer 34 of each of the red electroluminescent element and the green electroluminescent element has a thickness of 25 nm to 50 nm and a guest compound concentration of 0.1 to 10 wt %. The first electroluminescent layer 34 of the blue electroluminescent element has a thickness of 10 to 25 nm and a guest compound concentration of 0.1 to 10 wt %. A thickness and a guest compound concentration (a dopant concentration) of the second electroluminescent layer 53 vary depending on a color of the light to be emitted. For example, the second electroluminescent layer 53 of each of a red electroluminescent element and a green electroluminescent element has a thickness of 25 nm to 50 nm and a guest compound concentration of 0.1 to 15 wt %. The second electroluminescent layer 53 of a blue electroluminescent element has a thickness of 10 to 25 nm and a guest compound concentration of 0.1 to 15 wt %. Note that the concentration of the guest compound contained in the first electroluminescent layer 34 is set higher than the concentration of the guest compound contained in the second electroluminescent layer 53.

### Method for Manufacturing Electroluminescent Element

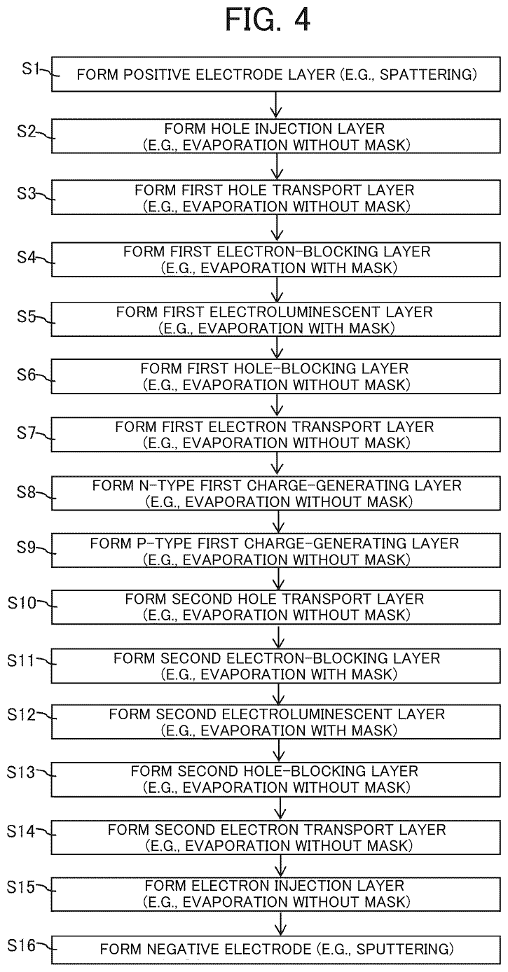

Described next with reference to FIG. 4 will be an exemplary method for manufacturing the electroluminescent element 10. FIG. 4 is a flowchart showing an exemplary method for manufacturing the electroluminescent element illustrated in FIG. 3.

As shown in FIG. 4, at Step S1, the positive electrode layer 21 is formed on the TFT layer 20. Specifically, an Ag layer and an indium tin oxide (ITO) layer are sequentially formed by sputtering.

At Step S2, the hole injection layer 31 is formed on the positive electrode layer 21. Specifically, a hole transport material and an electron acceptance material are simultaneously evaporated at a predetermined evaporation rate, with evaporation temperatures and evaporation time periods of the respective materials adjusted so that the materials are stacked with predetermined thicknesses at a predetermined ratio. Here, without using a fine metal mask, the evaporation film is formed uniformly on the entire surface of the work.

Note that, in the specific description of the manufacturing method in FIG. 4, a common layer is formed among the electroluminescent elements of all the colors for some carrier functional layers. However, the manufacturing method of the present disclosure shall not be limited to such a method. Each of the carrier functional layers may have a different thickness for a different color in accordance with, for example, the electroluminescent layer in the color. As can be seen, the carrier functional layer having partially different thicknesses can be formed by evaporation through a mask.

At Step S3, the first hole transport layer 32 is formed on the hole injection layer 31. Specifically, a hole transport material is evaporated at a predetermined evaporation rate, with an evaporation temperature and an evaporation time period of the material adjusted so that the material is stacked with a predetermined thickness. Here, without using a fine metal mask, the evaporation film is formed.

At Step S4, the first electron blocking layer 33 is formed on the first hole transport layer 32. Specifically, a hole transport material is evaporated at a predetermined evaporation rate, with an evaporation temperature and an evaporation time period of the material adjusted so that the material is stacked with a predetermined thickness. Here, a fine metal mask is used so that the hole transport material is evaporated to have a first thickness corresponding to each of the colors. The first thickness may be the same or different in the colors of the electroluminescent elements.

At Step S5, the first electroluminescent layer 34 is formed on the first electron blocking layer 33. Specifically, a host compound 34H and guest compound 34U (a dopant) are simultaneously evaporated at a predetermined evaporation rate, with evaporation temperatures and evaporation time periods of the respective compounds adjusted so that the compounds are stacked with predetermined thicknesses while the guest compound 34U has a predetermined guest compound concentration (a dopant concentration). Here, a fine metal mask is used so that the materials corresponding to the colors are evaporated while the thicknesses of the materials and the concentration of the guest compound are precisely controlled.

At Step S6, the first hole blocking layer 35 is formed on the first electroluminescent layer 34. Specifically, an electron transport material is evaporated at a predetermined evaporation rate, with an evaporation temperature and an evaporation time period of the material adjusted so that the material is stacked with a predetermined thickness. Here, without using a fine metal mask, the evaporation film is formed.

At Step S7, the first electron transport layer 36 is formed on the first hole blocking layer 35. Specifically, an electron transport material is evaporated at a predetermined evaporation rate, with an evaporation temperature and an evaporation time period of the material adjusted so that the material is stacked with a predetermined thickness. The evaporation may involve simultaneous evaporation of the electron transport material and lithium quinoline. Here, without using a fine metal mask, the evaporation film is formed.

At Step S8, the n-type first charge generation layer 41 is formed on the first electron transport layer 36. Specifically, an organic electron transport material and either Yb or Li, which is an inorganic metal material serving as an electron supply material, are simultaneously evaporated at a predetermined evaporation rate, with evaporation temperatures and evaporation time periods of the respective materials adjusted so that the materials are stacked with predetermined thicknesses at a predetermined ratio. Here, without using a fine metal mask, the evaporation film is formed.

At Step S9, the p-type first charge generation layer 42 is formed on the n-type first charge generation layer 41. Specifically, an organic hole transport material and an organic electron acceptance material are simultaneously evaporated at a predetermined evaporation rate, with evaporation temperatures and evaporation time periods of the respective materials adjusted so that the materials are stacked with predetermined thicknesses at a predetermined ratio. Here, without using a fine metal mask, the evaporation film is formed.

At Step S10, the second hole transport layer 51 is formed on the p-type first charge generation layer 42.

Specifically, a hole transport material is evaporated at a predetermined evaporation rate, with an evaporation temperature and an evaporation time period of the material adjusted so that the material is stacked with a predetermined thickness. Here, without using a fine metal mask, the evaporation film is formed.

At Step S11, the second electron blocking layer 52 is formed on the second hole transport layer 51. Specifically, a hole transport material is evaporated at a predetermined evaporation rate, with an evaporation temperature and an evaporation time period of the material adjusted so that the material is stacked with a predetermined thickness. Here, a fine metal mask is used so that the hole transport material is evaporated to have a second thickness corresponding to each of the colors. Similar to the first thickness, the second thickness may also be the same or different in the colors of the electroluminescent elements.

At Step S12, the second electroluminescent layer 53 is formed on the second electron blocking layer 52. Specifically, a host compound 53H and guest compound 53U (a dopant) are simultaneously evaporated at a predetermined evaporation rate, with evaporation temperatures and evaporation time periods of the respective compounds adjusted so that the compounds are stacked with predetermined thicknesses while the guest compound 34U has a predetermined guest compound concentration (a dopant concentration). Here, a fine metal mask is used so that the materials corresponding to the colors are evaporated while the thicknesses of the materials and the concentration of the guest compound are precisely controlled.

At Step S13, the second hole blocking layer 54 is formed on the second electroluminescent layer 53. Specifically, an electron transport material is evaporated at a predetermined evaporation rate, with an evaporation temperature and an evaporation time period of the material adjusted so that the material is stacked with a predetermined thickness. Here, without using a fine metal mask, the evaporation film is formed.

At Step S14, the second electron transport layer 55 is formed on the second hole blocking layer 54. Specifically, an electron transport material is evaporated at a predetermined evaporation rate, with an evaporation temperature and an evaporation time period of the material adjusted so that the material is stacked with a predetermined thickness. The evaporation may involve simultaneous evaporation of the electron transport material and lithium quinoline. Here, without using a fine metal mask, the evaporation film is formed.

At Step S15, the electron injection layer 56 is formed on the second electron transport layer 55. Specifically, lithium fluoride is evaporated at a predetermined evaporation rate, with an evaporation temperature and an evaporation time period of the material adjusted so that the lithium fluoride is stacked with a predetermined thickness. Here, without using a fine metal mask, the evaporation film is formed.

At Step S16, the negative electrode layer 22 is formed on the electron injection layer 56. Specifically, by evaporation, a thin film is formed of, for example, an alloy of magnesium and silver.

A method for manufacturing the electroluminescent device 13 includes steps of alternately stacking, for either the positive electrode layer 21 or the negative electrode layer 22, one of the first electroluminescent layer 34 or the second electroluminescent layer 53 and the first charge generation layer 40. Each of the first electroluminescent layer 34 and the second electroluminescent layer 53 is formed by evaporation.

Focusing on steps S5 and S12, the following can be understood. In forming the first electroluminescent layer 34 and the second electroluminescent layer 53 that emit light in the stacking direction in the same color, the evaporation time periods of the guest compounds 34U and 53U may be set different between the first electroluminescent layer 34 and the second electroluminescent layer 53. In forming the first electroluminescent layer 34 and the second electroluminescent layer 53 that emit light in the stacking direction in the same color, only the evaporation time periods of the guest compounds 34U and 53U may be set different between the first electroluminescent layer 34 and the second electroluminescent layer 53. In forming the first electroluminescent layer 34 and the second electroluminescent layer 53 that emit light in the stacking direction in the same color, the evaporation temperatures of the guest compounds 34U and 53U may be set different between the first electroluminescent layer 34 and the second electroluminescent layer 53.

### Mechanism for Emitting Light

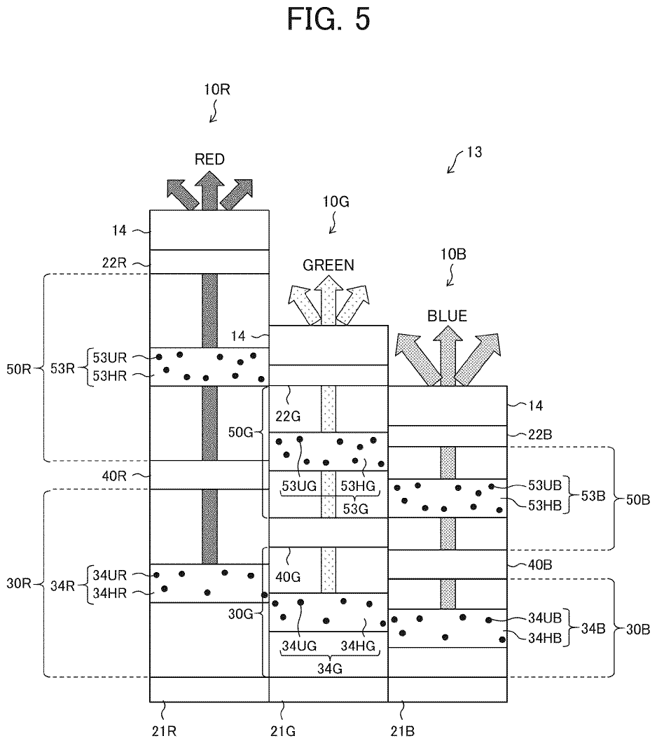

With reference to FIG. 5, a light emission mechanism will be described as to the electroluminescent element 10 of the electroluminescent device 13 capable of full color display. FIG. 5 is a view showing a mechanism for emitting light from the electroluminescent element of the electroluminescent device 13 in FIG. 2. FIG. 5 illustrates only main components of the electroluminescent element 10.

In FIG. 5, the electroluminescent element 10 is an organic-EL element having a tandem structure. The organic-EL element includes two electroluminescent layers of the first electroluminescent layer 34 and the second electroluminescent layer 53 arranged between the positive electrode layer 21 and the negative electrode layer 22. Between the first electroluminescent layer 34 and the second electroluminescent layer 53, the first charge generation layer 40 is disposed. In the example illustrated in FIG. 5, each of the red electroluminescent element 10R, the green electroluminescent element 10G, and the blue electroluminescent element 10B includes the first electroluminescent layer 34 and the second electroluminescent layer 53 stacked together to emit light in the same color.

More specifically, as illustrated in FIG. 5, the red electroluminescent element 10R includes: the positive electrode layer 21R; the first electroluminescent layer 34R; the first charge generation layer 40R; the second electroluminescent layer 53R; and the negative electrode layer 22R, all of which are disposed in the stated order. In the red electroluminescent element 10R, the first stack is a layer group 30R disposed between the positive electrode layer 21R and the first charge generation layer 40R in the stacking direction and including the first electroluminescent layer 34R. Furthermore, the second stack is a layer group 50R disposed between the first charge generation layer 40R and the negative electrode layer 22R and including the second electroluminescent layer 53R.

Likewise, the green electroluminescent element 10G includes: the positive electrode layer 21G; the first electroluminescent layer 34G; the first charge generation layer 40G; the second electroluminescent layer 53G; and the negative electrode layer 22G, all of which are disposed in the stated order. In the green electroluminescent element 10G, the first stack is a layer group 30G disposed between the positive electrode layer 21G and the first charge generation layer 40G in the stacking direction and including the first electroluminescent layer 34G. In the green electroluminescent element 10G, the second stack is a layer group 50G disposed between the first charge generation layer 40G and the negative electrode layer 22G and including the second electroluminescent layer 53G.

Furthermore, the blue electroluminescent element 10B includes: the positive electrode layer 21B; the first electroluminescent layer 34B; the first charge generation layer 40B; the second electroluminescent layer 53B; and the negative electrode layer 22B, all of which are stacked in the stated order. In the blue electroluminescent element 10B, the first stack is a layer group 30B disposed between the positive electrode layer 21B and the first charge generation layer 40B in the stacking direction and including the first electroluminescent layer 34B. In the blue electroluminescent element 10B, the second stack is a layer group 50B disposed between the first charge generation layer 40B and the negative electrode layer 22B and including the second electroluminescent layer 53B.

Here, the negative electrode layer 22R, the negative electrode layer 22G, and the negative electrode layer 22B are respectively provided to the red electroluminescent element 10R, the green electroluminescent element 10G, and the blue electroluminescent element 10B. The negative electrode layers 22R, 22G and 22B may be a common electrode layer provided across the red electroluminescent element 10R, the green electroluminescent element 10G, and the blue electroluminescent element 10B.

Furthermore, as illustrated in FIG. 5, each of the red electroluminescent element 10R, the green electroluminescent element 10G, and the blue electroluminescent element 10B has an upper most portion provided with the sealing layer 14 for preventing such substances as oxygen and water from penetrating into the respective elements. The sealing layer 14 may also be a common electrode layer provided across the red electroluminescent element 10R, the green electroluminescent element 10G, and the blue electroluminescent element 10B.

Note that each of the layer groups 30R, 30G, 30B, 50R, 50G, and 50B included in the electroluminescent elements 10R, 10G, and 10B in the respective colors is provided with not-shown carrier functional layers (such as an electron injection layer, an electron transport layer, a hole transport layer, and a hole injection layer).

Described further below will be the mechanism for emitting light from the electroluminescent element 10. In the description below, the red electroluminescent element 10R, the green electroluminescent element 10G, and the blue electroluminescent element 10B share the same light emission mechanism. Hence, the description below will be given without signs R, G, and B denoting the colors and added to the signs representing the basic features.

When a current flows in the electroluminescent element 10, holes are supplied from the positive electrode layer 21 to the first electroluminescent layer 34, and, simultaneously, electrons are supplied from the negative electrode layer 22 to the second electroluminescent layer 53. Furthermore, when a current flows in the electroluminescent element 10, the electrons generated by the n-type first charge generation layer 41 are supplied to the first electroluminescent layer 34, and, simultaneously, the holes generated by the p-type first charge generation layer 42 are supplied to the second electroluminescent layer 53.

As a result, the electrons and the holes are recombined together in the first electroluminescent layer 34 to generate electron-hole pairs (also referred to as excitons). The electron-hole pairs transform to the ground state, thereby emitting light in a predetermined wavelength region. Furthermore, the electrons and the holes are recombined together in the second electroluminescent layer 53 to generate electron-hole pairs. The electron-hole pairs transform to the ground state, thereby emitting light in a predetermined wavelength region (light in the same color as the color of the first electroluminescent layer 34). For example, each of the first electroluminescent layer 34R and the second electroluminescent layer 53R of the red electroluminescent element 10R emits light in red. Likewise, each of the first electroluminescent layer 34G and the second electroluminescent layer 53G of the green electroluminescent element 10G emits light in green, and each of the first electroluminescent layer 34B and the second electroluminescent layer 53B of the blue electroluminescent element 10B emits light in blue.

Here, both the first electroluminescent light 34 and the second electroluminescent layer 53 can emit light at light emission efficiency substantially equivalent to a theoretical value. Hence, any of the plurality of light emitting layers having the same color and disposed in the stacking direction emit light substantially at the same level as the theoretical value, so that the light emitting layers are used for forming a full color image with high luminance and high definition.

However, as to a known electroluminescent element not having the electroluminescent layer described in the present disclosure; that is, a known tandem electroluminescent element including two host/guest electroluminescent layers emitting light in the same color, having the same guest compound concentration, and stacked together, the amount of light emitted from the known electroluminescent element might not reach twice (i.e., a theoretical value) the amount of light emitted from an electroluminescent element having one electroluminescent layer.

Here, introduced below will be results of a study conducted by the inventors of the disclosure.

First, an electroluminescent element (a single prototype) was produced to include one blue electroluminescent layer (also referred to as a single blue electroluminescent layer; a single structure). In addition, tandem electroluminescent elements (comparative tandem prototypes) were produced to each include two such blue electroluminescent layers. Each of the comparative tandem prototypes was a known tandem electroluminescent element; specifically, the electroluminescent layers stacked together in the stacking direction had the same guest compound concentration. The single prototype is produced under the conditions below. The comparative tandem prototypes are produced under the three respective conditions from Condition i to Conditions iii below. Between the negative electrode layer and the positive electrode layer, the single prototype has the same layer configuration as that of the first stack under Condition i. Each of the comparative tandem prototypes was a known tandem electroluminescent element; specifically, the electroluminescent layers stacked together in the stacking direction had the same guest compound concentration (the same doping concentration). Then, for each of the prototypes, the element lifetime and the drive voltage were measured, and the current efficiency was obtained using the Blue Index (unit: cd/A/y, where y is one of chromaticity coordinates in the CIE 1931).

### Single Prototype

Layer Configuration: Negative Electrode Layer/First Stack (Electron Transport Layer/Hole Blocking Layer/First Blue Electroluminescent Layer (Guest Compound Concentration: 0.3 wt %)/Electron Blocking Layer/Hole Transport Layer/Hole Injection Layer)/Positive Electrode Layer.

### Condition i

Layer Configuration: Negative Electrode Layer/Second Stack (Electron Injection Layer/Electron Transport Layer/Hole Blocking Layer/Second Blue Electroluminescent Layer (Guest Compound Concentration: 0.3 wt %)/Hole Transport Layer/Hole Injection Layer)/Charge Generation Layer/First Stack (Electron Transport Layer/Hole Blocking Layer/First Blue Electroluminescent Layer (Guest Compound Concentration: 0.3 wt %)/Electron Blocking Layer/Hole Transport Layer/Hole Injection Layer)/Positive Electrode Layer.
Total Organic Layer Thickness: 235 nm.

### Condition ii

Layer Configuration: Same as Condition i.

Thickness Ratio: Same as Condition i except that thicknesses of the carrier functional layers in the second stack were adjusted such that the total thickness was 255 nm.

### Condition iii

Layer Configuration: Same as Condition i.

Thickness Ratio: Same as Condition i except that thicknesses of the carrier functional layers in the second stack were adjusted such that the total thickness was 215 nm.

As a result, the single prototype had a current efficiency of 206 cd/A/y. Whereas, the comparative tandem prototypes had: a current efficiency (under Condition i) of 305 cd/A/y (i.e., the current efficiency was 1.48 times higher than that of the single prototype), a current efficiency (under Condition ii) of 320 cd/A/y (the current efficiency was 1.55 times higher than that of the single prototype), and a current efficiency (under Condition iii) of 219 cd/A/y (the current efficiency was 1.1 times higher than a current efficiency of the single prototype). Furthermore, when element lifetimes were measured, the element lifetimes of the comparative tandem prototypes were 2.01 times (under Condition i), 2.12 times (under Condition ii), and 1.92 times (under Condition iii) longer than an element lifetime of the simple prototype. Furthermore, when drive voltages were measured, the driving voltages of the comparative tandem prototypes were 1.9 times (under Condition i), 1.9 times (under Condition ii), and 2.0 times (under Condition iii) than a drive voltage of the simple prototype.

From the above results, the study shows that the known double-layer tandem electroluminescent elements, with the conditions of the carrier functional layers changed except for the electroluminescent layer, are improved to have the element lifetimes approximately more or less twice the element lifetime of the single electroluminescent element. Whereas, the study shows that the known tandem electroluminescent elements, each having two electroluminescent layers with the same guest compound concentration, exhibit only a small increase in current efficiency in relation to an increase in drive voltage, compared with the single electroluminescent element. Even though the conditions of the carrier functional layers are changed, and the driving voltage is raised approximately twice, the light emission efficiency of each of the tandem electroluminescent elements is not even close to twice the light emission efficiency of the single electroluminescent element.

These results clearly show that, in order to increase the light emission efficiency of the known double-layer tandem electroluminescent element twice the light emission efficiency of the single electroluminescent element, a higher driving voltage would be applied, and a larger amount of current would be supplied. As a result, however, it is apparent that the power consumption would increase, and the element lifetime would decrease. That is, it is understood that there is still room to study in order to sufficiently achieve the advantageous effects of employing the tandem structure for the known structure. Based on the study, the inventors of the disclosure have come to the reasons below.

Typically, as to the known electroluminescent element having one electroluminescent layer, the material selection of the carrier functional layers other than the electroluminescent layer or the thicknesses of the carrier functional layers are optimized so that the amount of carriers to be supplied to the electroluminescent layer is equalized; that is, some efforts are made to balance the amount of carriers. Furthermore, in order to solve the problem of the carrier balance of each electroluminescent layer in the tandem electroluminescent element, the same countermeasures as those for the electroluminescent element having one electroluminescent layer have been taken; that is, as described above, optimizing the carrier functional layers around the electroluminescent layer other than the electroluminescent layer. In the tandem electroluminescent element, a charge generation layer is sandwiched between two electroluminescent layers adjacent to each other in the stacking direction. The balance of the electrons and the holes generated by the charge generation layer might not be 1:1. Typically, the electrons are injected less from the charge generation layer than from the negative electrode. As a result, the amount of electrons to be supplied is likely to be short in generating excitons. In other words, in the first electroluminescent layer, the holes are likely to be supplied in excess amount. Furthermore, the n-type charge generation layer has, as a mainstream structure, an organic-inorganic hybrid structure in which an organic electron transport material is doped with a small amount of metal material. However, recent years have seen progress in development of an n-type charge generation layer containing an organic material alone as seen in a p-type charge generation layer, in view of preventing deterioration of an organic material in another layer because of a rise in evaporation temperature. However, under present circumstances, the amount of electrons to be supplied from the n-type charge generation layer formed entirely of an organic material can be significantly smaller than the amount of holes to be supplied from the p-type charge generation layer. Hence, the tandem electroluminescent element has difficulty in matching the amounts of supplied electrons and holes between two electroluminescent layers adjacent in the stacking direction across the charge generation layer.

Furthermore, as described before, if a microcavity structure is to be used to increase efficiency in releasing light, the electroluminescent layers cannot be set at any given position. Each of the electroluminescent layers has to be set at any one of periodical positions depending on the emission wavelength and the refractive index. In addition to the positional limitation of the electroluminescent layers because of this microcavity condition, there is another limitation; that is, the positive electrode layer and one hole transport layer formed between the positive electrode layer and an electroluminescent layer above the positive electrode layer have to be formed thicker than another hole transport layer because of a phenomenon; that is, if the positive electrode layer and the electroluminescent layer are formed adjacent to each other, the formed layers develop an interaction to inevitably cause quenching. However, if the one hole transport layer is formed thick, the holes are likely to deactivate in relation to the other hole transport layer. As a result, an additional phenomenon inevitably occurs; that is, there is a decrease in the amount of holes to be supplied to the electroluminescent layer formed immediately above the positive electrode layer. Because of these phenomena, the tandem electroluminescent element having a microcavity structure has a further difficulty in matching the amounts of supplied electrons and holes between the electroluminescent layers adjacent in the stacking direction.

That is, as the above study shows, the tandem electroluminescent element might not sufficiently achieve an advantageous effect yet as to conventionally-performed optimization of the carrier functional layers provided around, and excluding, an electroluminescent layer. Furthermore, there is room left to study countermeasures to a new problem; that is, a known tandem electroluminescent element, including two electroluminescent layers having the same guest compound concentration, emits light an amount of which is not even close twice the amount of light emitted from an electroluminescent element having one electroluminescent layer.

In order to solve this problem, the inventors of the disclosure have focused on mobility of carriers in the stacking direction, and injection of the carriers, in a tandem electroluminescent element including a plurality of electroluminescent layers. The inventors have focused further on the amount of carriers to be supplied, and the amount of excess carriers generated, in each of the electroluminescent layers. As a result, the inventors of the disclosure have found out the following. In the plurality of electroluminescent layers stacked through a charge generation layer, if the electrons are supplied in controlled amount to an electroluminescent layer closer to the negative electrode layer, the carriers (electrons) are to be supplied in smaller amount to the electroluminescent layer stacked closer toward the positive electrode layer than to an electroluminescent layer stacked closer to the negative electrode layer. Thus, there is shortage in the amount of suppled electrons available for combination with the holes in the electroluminescent layer stacked closer to the positive electrode layer. As a result, the amount of electron-hole pairs (excitons) to be generated by recombination is relatively small. That is, even if two or more electroluminescent layers are provided, the amount of excitons is not increased twice or more. As a result, the inventors of the disclosure have found out the following. If two electroluminescent layers having the same dopant concentration are found as seen in a known tandem electroluminescent element, the amount of light to be emitted might not be doubled. Furthermore, the inventors of the disclosure have found out the following. In the known tandem electroluminescent element, the electroluminescent layer formed closer to the positive electrode layer generates excess holes, which might be a reason why the current efficiency of the electroluminescent element would not be doubled.

As to the tandem electroluminescent element including a plurality of electroluminescent layers, the inventors of the disclosure have introduced a new design concept of changing the concentration of a guest compound (a dopant) in each of the electroluminescent layers as described in the present disclosure. Such a concept attains a balance of the carriers between the plurality of electroluminescent layers and solves a problem of imbalance in the amount of carriers to be supplied. The concept in the present disclosure allows each of the electroluminescent layers to generate excitons in appropriate amount and balance, without generating excess carriers (holes) found in a known tandem electroluminescent element. As a result, the electroluminescent device of the present disclosure can operate on less power and lower drive voltage and improves in light emission efficiency.

Hence, in the present disclosure, as described above, the electrons are injected in small amount into the electroluminescent layer closer to the positive electrode layer. As a result, taking into consideration the shortage in the amount of electrons to be supplied to the electroluminescent layer closer to the positive electrode layer, the guest compound concentration (the dopant concentration) is set lower for the electroluminescent layer formed closer to the positive electrode layer than for the electroluminescent layer formed closer to the negative electrode layer. As a result, the supply of holes to the electroluminescent layer closer to the positive electrode layer can be adjusted to be commensurate with the guest compound concentration (the dopant concentration) of the electroluminescent layer. Such a feature allows the emitted light to have luminance commensurate with the guest compound concentration (the dopant concentration). In addition, the feature reduces injection of excess holes into the electroluminescent layer closer to the positive electrode layer so that the excitons are generated substantially in the amount indicated by a theoretical value. Hence, any given electroluminescent layer overlapping in the stacking direction emits light in the luminance based on the guest compound concentration (the dopant concentration) of the electroluminescent layer. Furthermore, any given electroluminescent layer is kept from the injection (the supply) of excess holes. Such a feature reduces consumption of current, thereby contributing to the resulting reduction in power consumption. Furthermore, the feature contributes to reduction in the amount of the guest compound (the dopant) to be used.

Note that, in particular, in the case of a top-emission electroluminescent element that releases light from toward the negative electrode layer, even a slight defect in the sealing layer formed on the negative electrode layer might deteriorate the negative electrode layer because of intrusion of oxygen or water and reduce capability for injecting electrons. As a result, there might be shortage in the amount of electrons to be supplied to the electroluminescent layer immediately below the negative electrode layer. However, if such a case is taken into consideration, and the guest compound concentration (the dopant concentration) of the electroluminescent layer closer to the negative electrode layer is set below the theoretical value at the initial designing stage, the electroluminescent layer closer to the negative electrode layer can be kept from generating excess holes. From such a viewpoint, it is suitable in the present disclosure to set the guest compound concentration (the dopant concentration) of the electroluminescent layer closer to the negative electrode layer below the theoretical value within a range in which the advantageous effects of the present disclosure are obtained.

Here, an evaluation based on simulations will be described as to the full color electroluminescent devices according to an example of the present disclosure and a comparative example. Each of the electroluminescent devices has two electroluminescent layers (a tandem structure). A condition of the electroluminescent device was determined as follows. The electroluminescent layer closer to the negative electrode layer had a dopant concentration of 5 wt % in each of the red electroluminescent element and the green electroluminescent element, and 3 wt % in the blue electroluminescent element. The electroluminescent layer closer to the positive electrode layer had a dopant concentration of 3 wt % in each of the red and green electroluminescent elements, and 2 wt % in the blue electroluminescent element. Here, the dopant concentration of the electroluminescent layer closer to the negative electrode layer is lower than, or equal to, twice the dopant concentration of the electroluminescent layer closer to the positive electrode. If the dopant concentration is higher than twice, the electroluminescent layer provided closer to the negative electrode layer and having a high dopant concentration causes quenching by itself, such that generated excitons are consumed wastefully. Furthermore, the electroluminescent layer provided closer to the positive electrode layer and having a low dopant concentration might not generate sufficient excitons.

The result of the simulations under the above condition shows that, the full color electroluminescent device of the example was 1.8 times greater in current efficiency (also referred to as “light emission efficiency”), 2.9 times longer in element lifetime, and 1.8 times higher in drive voltage than the full color electroluminescent device of the comparative example. The result shows that the electroluminescent elements of the example achieve an improvement in light emission efficiency that matches the rise in the drive voltage. Hence, compared with the known tandem full color electroluminescent device including two electroluminescent layers having the same guest compound concentration, the electroluminescent device of the present disclosure can reduce a rise in the drive voltage and achieve an improvement in light emission efficiency that matches the rise in the drive voltage.

Furthermore, under the conditions for the simulations in the example, the drive voltage was further raised to further improve the current efficiency (the light emission efficiency). As a result, when the drive voltage is doubled. the current efficiency was also doubled, and the element lifetime under the conditions was increased by 2.6 times. That is, the full color electroluminescent device according to the present disclosure and having two electroluminescent layers (a tandem structure) can achieve properties twice as great as the properties of the full color electroluminescent device having one electroluminescent layer.

Moreover, as to the blue electroluminescent element, a comparison between the example and the comparative example shows that the current efficiency and the element lifetime of the electroluminescent device according to the example are respectively increased by 12.5% and 17.1% with respect to the current efficiency and the element lifetime of the electroluminescent device according to the comparative example. The drive voltage of the electroluminescent device according to the example is decreased by 12.9% with respect to the drive voltage of the electroluminescent device according to the comparative example. This result clearly shows that the electroluminescent device according to this embodiment can achieve a significant improvement in properties.

### Second Embodiment

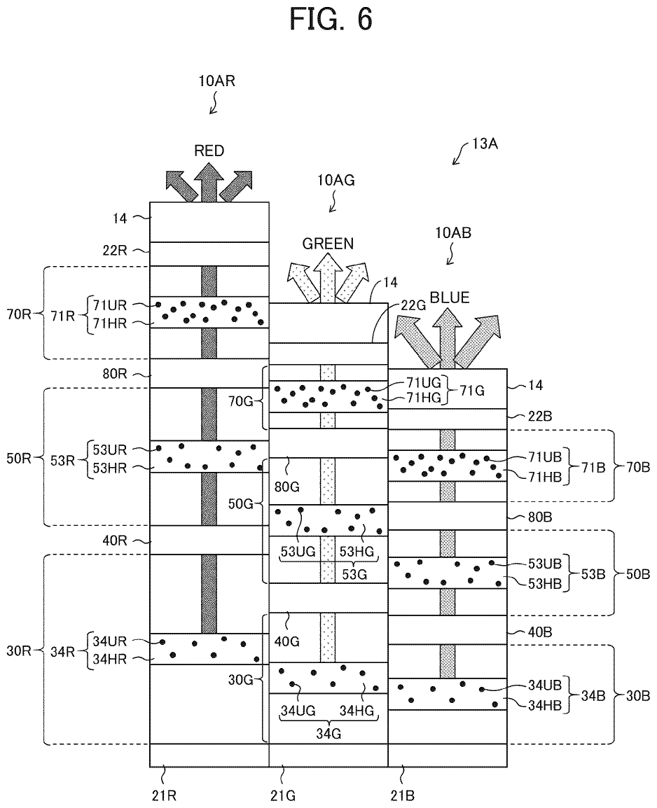

A second embodiment of the present disclosure will be described below, with reference to FIG. 6. FIG. 6 is a view showing a mechanism for emitting light from an electroluminescent element 10A of an electroluminescent device 13A according to a second embodiment of the present disclosure. The electroluminescent device 13A according to the second embodiment is different from the electroluminescent device 13 described above in that the electroluminescent device 13A includes an electroluminescent element 10A having three electroluminescent layers in the stacking direction.

Note that FIG. 6 shows only main components of the electroluminescent element 10A included in the electroluminescent device 13A. In the embodiment below, for convenience in description, like description between this embodiment and the above embodiment will not be elaborated upon repeatedly. Like reference signs designate members having identical functions between this embodiment and the above embodiment. These members will not be elaborated upon repeatedly.

As illustrated in FIG. 6, a red electroluminescent element 10AR further includes a third electroluminescent layer 71R and a second charge generation layer 80 between the negative electrode layer 22R and the second electroluminescent layer 53R. In the red electroluminescent element 10AR, the second stack is the layer group 50R disposed between the first charge generation layer 40R and the second charge generation layer 80R in the stacking direction and including the second electroluminescent layer 53R. Furthermore, a third stack is a layer group 70R disposed between the second charge generation layer 80R and the negative electrode layer 22R and including the third electroluminescent layer 71R.

Likewise, a green electroluminescent element 10AG further includes a third electroluminescent layer 71G and a second charge generation layer 80G between the negative electrode layer 22G and the second electroluminescent layer 53G. In the green electroluminescent element 10AG, the second stack is the layer group 50G disposed between the first charge generation layer 40G and the second charge generation layer 80G in the stacking direction and including the second electroluminescent layer 53G. Furthermore, a third stack is a layer group 70G disposed between the second charge generation layer 80G and the negative electrode layer 22G and including the third electroluminescent layer 71G.

Moreover, a blue electroluminescent element 10AB further includes a third electroluminescent layer 71B and a second charge generation layer 80B between the negative electrode layer 22B and the second electroluminescent layer 53B. In the blue electroluminescent element 10AB, the second stack is the layer group 50B disposed between the first charge generation layer 40B and the second charge generation layer 80B in the stacking direction and including the second electroluminescent layer 53B. Furthermore, a third stack is a layer group 70B disposed between the second charge generation layer 80B and the negative electrode layer 22B and including the third electroluminescent layer 71B.

Note that each of the layer groups 30R, 30G, 30B, 50R, 50G, 50B, 70R, 70G, and 70B included in the electroluminescent elements 10AR, 10AG, and 10AB in the respective colors is provided with not-shown carrier functional layers (such as an electron injection layer, an electron transport layer, a hole transport layer, and a hole injection layer). Moreover, in the description below, the third electroluminescent layers 71R, 71G, and 71B included in the electroluminescent elements 10AR, 10AG, and 10AB in the respective colors are collectively referred to as a “third electroluminescent layer 71”.

The third electroluminescent layer 71R contains: a host compound 71HR; and a guest compound 71UR. The third electroluminescent layer 71G contains: a host compound 71HG; and a guest compound 71UG. The third electroluminescent layer 71B contains: a host compound 71HB; and a guest compound 71UB.

The host compound 53HR and the host compound 71HR are formed of the same material. The host compound 53HG and the host compound 71HG are formed of the same material. The host compound 53HB and the host compound 71HB are formed of the same material.

The guest compound 53UR and the guest compound 71UR are formed of the same material. The guest compound 53UG and the guest compound 71UG are formed of the same material. The guest compound 53UB and the guest compound 71UB are formed of the same material.

A concentration of the guest compound 71UR in the third electroluminescent layer 71R is higher than a concentration of the guest compound 53UR in the second electroluminescent layer 53R. A concentration of the guest compound 71UG in the third electroluminescent layer 71G is higher than a concentration of the guest compound 53UG in the second electroluminescent layer 53G. A concentration of the guest compound 71UB in the third electroluminescent layer 71B is higher than a concentration of the guest compound 53UB in the second electroluminescent layer 53B.

In the stacking direction, the first electroluminescent layer 34, the second electroluminescent layer 53, and the third electroluminescent layer 71 (three or more electroluminescent layers) are disposed. Among the first electroluminescent layer 34, the second electroluminescent layer 53, and the third electroluminescent layer 71, a layer farther away from the positive electrode layer 21 may exhibit a higher concentration of a guest compound among the guest compounds 34U, 53U, and 71U.

In this embodiment, three electroluminescent layers are disposed in the stacking direction. Alternatively, four or more electroluminescent layers may be disposed. Whereas, preferably, five or fewer electroluminescent layers may be disposed in the stacking direction. Three or more electroluminescent layers are preferably five or fewer electroluminescent layers.

In the first electroluminescent layer 34R, the second electroluminescent layer 53R, and the third electroluminescent layer 71R, a difference of 10 nm or less may be observed between a maximum value of a peak wavelength of an emission spectrum and a minimum value of a peak wavelength of an emission spectrum. In the first electroluminescent layer 34G, the second electroluminescent layer 53G, and the third electroluminescent layer 71G, a difference of 10 nm or less may be observed between a maximum value of a peak wavelength of an emission spectrum and a minimum value of a peak wavelength of an emission spectrum. In the first electroluminescent layer 34B, the second electroluminescent layer 53B, and the third electroluminescent layer 71B, a difference of 10 nm or less may be observed between a maximum value of a peak wavelength of an emission spectrum and a minimum value of a peak wavelength of an emission spectrum.

In the first electroluminescent layer 34R, the second electroluminescent layer 53R, and the third electroluminescent layer 71R, a maximum value of full width at half maximum of a peak wavelength of an emission spectrum may be 1.25 times or less than a minimum value of full width at half maximum of a peak wavelength of an emission spectrum. In the first electroluminescent layer 34G, the second electroluminescent layer 53G, and the third electroluminescent layer 71G, a maximum value of full width at half maximum of a peak wavelength of an emission spectrum may be 1.25 times or less than a minimum value of full width at half maximum of a peak wavelength of an emission spectrum. In the first electroluminescent layer 34B, the second electroluminescent layer 53B, and the third electroluminescent layer 71B, a maximum value of full width at half maximum of a peak wavelength of an emission spectrum may be 1.25 times or less than a minimum value of full width at half maximum of a peak wavelength of an emission spectrum.

In the electroluminescent device 13A according to the second embodiment, for example, a concentration of the guest compound 71U in the third electroluminescent layer 71 receiving a limited amount of controlled carriers (the electrons) is set higher than a concentration of the guest compound 53U in the second electroluminescent layer 53. Such a feature optimizes the balance of the carriers among all the electroluminescent layers in the stacking direction.

Furthermore, in FIG. 6, the negative electrode layer 22 may be a common electrode layer provided across the red electroluminescent element 10AR, the green electroluminescent element 10AG, and the blue electroluminescent element 10AB. Likewise, the sealing layer 14 may also be a common electrode layer provided across the red electroluminescent element 10AR, the green electroluminescent element 10AG, and the blue electroluminescent element 10AB.

As illustrated in FIG. 6, even though three electroluminescent layers are disposed in the stacking direction, any of the electroluminescent layers emits light with substantially the same luminance and light emission efficiency as theoretical values, as seen in the display device 100 illustrated in FIG. 5.

This embodiment has the same advantageous effects as those of the first embodiment for the first electroluminescent layer 34 and the second electroluminescent layer 53 adjacent to each other in the stacking direction.

### Main Advantageous Effects

At present, an electroluminescent layer of an OLED can be formed of a host/guest material containing a host material doped with 0.05 to several wt % (mass concentration) of guest material (a dopant). The host/guest electroluminescent layer can emit light at quantum efficiency almost equivalent to a theoretical value.

As also referred to as a multiphoton organic-EL element, an organic-EL element employing a tandem structure can theoretically generate a plurality of excitons with one charge, and thus, for example, the current efficiency should be doubled with the double-layer tandem structure. However, as to a known tandem OLED including two or more electroluminescent layers stacked together, the amount of light emitted from all the two or more electroluminescent layers does not reach twice or more the amount of light emitted from one electroluminescent layer.

Typically, as to an organic material, the holes are higher in mobility than the electrons. That is, generation of excitons is likely to be controlled by the amount of electrons to be injected. In order to overcome such a problem, some efforts are made to an electron injection layer of an OLED with one electroluminescent layer. However, the tandem OLED is provided not with an electrode layer but with a charge generation layer (CGL) between individual electroluminescent layers stacked together. Hence, the electrons are injected in smaller amount from the CGL than from the negative electrode layer. Furthermore, a dopant material contained in the electron transport layer might have low electron transportability.

For these reasons, even if one of the electroluminescent layers, which contains a dopant in certain amount, ideally generates excitons (e.g., 100) by electron-hole combination, another one of the electroluminescent layers with the same structure (containing a dopant in the same amount) is supplied with limited charges (electrons) in insufficient amount. Hence, the excitons to be generated are inevitably below 100.

As a result, the inventors of the disclosure have found out that, as to the tandem OLED including two electroluminescent layers having dopants in the same amount, the current efficiency (amount of emitted light) is not twice as high as that of the OLED having one electroluminescent layer.

Assumed here is a tandem OLED in which electroluminescent layers only in the same color are stacked in the stacking direction when separately colored in RGB. The present disclosure focuses on the problems in injection from the CGL and transportation of carriers by the dopant material itself. That is, if the hole transportability of the dopant material is higher than the electron transportability, generation of the excitons is not necessarily controlled by the holes. Depending on such factors as configurations of organic layers other than the electroluminescent layers and configurations of the electrodes, generation of the excitons could be controlled by the electrons. Furthermore, also in the case where the injectability of the electrons is lower from the CGL than from the negative electrode layer, generation of the excitons is controlled by the electrons. As a result, the first electroluminescent layer closer to the positive electrode layer exhibits low efficiency in generating the excitons. Conversely, if the electron transportability of the dopant material is lower than the hole transportability, and the injectability of the electrons from the CGL is lower than the injectability of the electrons from the negative electrode layer, the amount of dopant not contributing to emission of light is larger in the first electroluminescent layer (the electroluminescent layer closer to the positive electrode) than in the second electroluminescent layer (the electroluminescent layer closer to the negative electrode layer).

Hence, in the present disclosure, in order to deal with these phenomena, the dopant concentration in a layer supplied with a smaller amount of controlled charges (electrons); that is, the first electroluminescent layer, is set lower than the dopant concentration in the second electroluminescent layer. In other words, the dopant concentration in the electroluminescent layer closer to the positive electrode layer is set lower than the dopant concentration in the electroluminescent layer closer to the negative electrode layer. If three or more electroluminescent layer are stacked, the dopant concentration is set to sequentially increase from toward the positive electrode layer to toward the negative electrode layer.

From the above discussion, it is understood that the present disclosure can provide an electroluminescent device having a plurality of electroluminescent layers (a tandem structure). The electroluminescent device achieves high light emission efficiency and operates on low drive voltage, contributing to reduction in power consumption and increase in lifetime.

The electroluminescent devices and the display devices of the present disclosure are expected to contribute to achieving such a goal as goal 9.4 “Upgrade all industries and infrastructures for sustainability, with increased resource-use efficiency and greater adoption of clean and environmentally sound technologies and industrial processes” included in sustainable development goals (SDGs) advocated by the United Nations.

The present disclosure shall not be limited to the embodiments described above, and can be modified in various manners within the scope of claims. he technical aspects disclosed in different embodiments are to be appropriately combined together to implement another embodiment. Such an embodiment shall be included within the technical scope of the present disclosure. Moreover, the technical aspects disclosed in each embodiment may be combined together to achieve a new technical feature.

1. An electroluminescent device, comprising:
a positive electrode layer;
a negative electrode layer facing the positive electrode layer in a stacking direction;
an electroluminescent layer including a plurality of electroluminescent layers disposed between the positive electrode layer and the negative electrode layer in the stacking direction, and in a direction intersecting with the stacking direction, the electroluminescent layers each containing a host compound and a guest compound; and
a charge generation layer disposed between two of the electroluminescent layers adjacent to each other in the stacking direction,
wherein the electroluminescent layers include:
a plurality of electroluminescent layers disposed in the stacking direction and configured to emit light in a same color; and
an electroluminescent layer in a first color to an electroluminescent layer in an n-th color each disposed in a direction intersecting with the stacking direction and configured to emit light in a different color (where n is an integer of n≥2), and
in the two electroluminescent layers adjacent in the stacking direction across the charge generation layer,
the host compound in the electroluminescent layer closer to the positive electrode layer and the host compound in the electroluminescent layer closer to the negative electrode layer are formed of a same material,
the guest compound in the electroluminescent layer closer to the positive electrode layer and the guest compound in the electroluminescent layer closer to the negative electrode layer are formed of a same material, and
a concentration of the guest compound in the electroluminescent layer closer to the negative electrode layer is higher than the guest compound in the electroluminescent layer closer to the positive electrode layer.

2. The electroluminescent device according to claim 1,
wherein a concentration of the guest compound in the electroluminescent layer closer to the negative electrode layer is lower than, or equal to, twice a concentration of the guest compound in the electroluminescent layer closer to the positive electrode layer.

3. The electroluminescent device according to claim 1,
wherein, in the two electroluminescent layers adjacent in the stacking direction across the charge generation layer, a difference of 10 nm or less is observed between a peak wavelength of an emission spectrum of the electroluminescent layer closer to the positive electrode layer and a peak wavelength of an emission spectrum of the electroluminescent layer closer to the negative electrode layer.

4. The electroluminescent device according to claim 1,
wherein, in the two electroluminescent layers adjacent in the stacking direction across the charge generation layer, full width at half maximum of a peak wavelength of an emission spectrum of the electroluminescent layer closer to the positive electrode layer is 0.8 times or more and 1.25 times or less than full width at half maximum of a peak wavelength of an emission spectrum of the electroluminescent layer closer to the negative electrode layer.

5. The electroluminescent device according to claim 1,
wherein, in the two electroluminescent layers adjacent in the stacking direction across the charge generation layer, the guest compound of the electroluminescent layer closer to the positive electrode layer and the guest compound of the electroluminescent layer closer to the negative electrode layer are either a fluorescent dopant or a phosphorescent dopant.

6. The electroluminescent device according to claim 1,
wherein the guest compound of the electroluminescent layer in a first color is a fluorescent dopant, and
the guest compound of the electroluminescent layer in a second color is a phosphorescent dopant.

7. The electroluminescent device according to claim 5,
wherein an emission spectrum of the electroluminescent layer containing the guest compound has a peak wavelength of 440 nm or more and 660 nm or less.

8. The electroluminescent device according to claim 1,
wherein, in the two electroluminescent layers adjacent in the stacking direction across the charge generation layer, the guest compound of the electroluminescent layer closer to the positive electrode layer and the guest compound of the electroluminescent layer closer to the negative electrode layer are a hole transport material.

9. The electroluminescent device according to claim 1,
wherein, in the two electroluminescent layers adjacent in the stacking direction across the charge generation layer, the guest compound of the electroluminescent layer closer to the positive electrode layer and the guest compound of the electroluminescent layer closer to the negative electrode layer are an electron transport material.

10. The electroluminescent device according to claim 1,
wherein the electroluminescent device is a top-emission electroluminescent device.

11. The electroluminescent device according to claim 1, further comprising
three or more electroluminescent layers included in the plurality of electroluminescent layers and disposed in the stacking direction,
wherein, among the three or more electroluminescent layers, an electroluminescent layer farther away from the positive electrode layer exhibits a higher concentration of the guest compound.

12. The electroluminescent device according to claim 11,
wherein the three or more electroluminescent layers are five or fewer electroluminescent layers included in the plurality of electroluminescent layers.

13. The electroluminescent device according to claim 1,
wherein, in the plurality of electroluminescent layers disposed in the stacking direction, a difference of 10 nm or less is observed between a maximum value of a peak wavelength of an emission spectrum and a minimum value of a peak wavelength of an emission spectrum.

14. The electroluminescent device according to claim 1,
wherein, in the plurality of electroluminescent layers disposed in the stacking direction, a maximum value of full width at half maximum of a peak wavelength of an emission spectrum is 1.25 times or less than a minimum value of full width at half maximum of a peak wavelength of an emission spectrum.

15. A display device comprising the electroluminescent device according to claim 1.

16. A method for manufacturing the electroluminescent device according to claim 1, the method comprising
a step of alternately stacking the electroluminescent layer and the charge generation layer with respect to the positive electrode layer or the negative electrode layer,
wherein the electroluminescent layer is formed by evaporation.

17. The method for manufacturing the electroluminescent device according to claim 16,
wherein, in forming a plurality of the electroluminescent layers that emits light in a same color in the stacking direction, an evaporation time period of the guest compound is different for each of the electroluminescent layers.

18. The method for manufacturing the electroluminescent device according to claim 17,
wherein, in forming the plurality of electroluminescent layers that emits light in a same color in the stacking direction, only an evaporation time period of the guest compound is different for each of the electroluminescent layers.

19. The method for manufacturing the electroluminescent device according to claim 16,
wherein, in forming a plurality of the electroluminescent layers that emits light in a same color in the stacking direction, an evaporation temperature of the guest compound is different for each of the electroluminescent layers.
